(19) United States
(12) Patent Application Publication
(10) Pub. No.: US 2022/0320404 A1
(43) Pub. Date: Oct. 6, 2022

(54) OPTOELECTRONIC SEMICONDUCTOR COMPONENT AND METHOD FOR PRODUCING AN OPTOELECTRONIC SEMICONDUCTOR COMPONENT

(71) Applicant: OSRAM Opto Semiconductors GmbH, Regensburg (DE)

(72) Inventor: Ivar Tangring, Regensburg (DE)

(21) Appl. No.: 17/764,032

(22) PCT Filed: Sep. 23, 2020
(86) PCT No.: PCT/EP2020/076567

§ 371 Date: Mar. 25, 2022

(30) Foreign Application Priority Data
Sep. 26, 2019 (DE) 10 2019 126 021.3

(51) Int. Cl. H01L 33/64; H01L 33/00

(52) U.S. Cl. CPC H01L 33/641; H01L 33/005; H01L 33/642; H01L 2933/0075

(57) ABSTRACT

In an embodiment an optoelectronic semiconductor component includes a heat dissipating structure having a plurality of protrusions and a radiation emitting semiconductor chip, wherein the semiconductor chip is arranged at the heat dissipating structure, wherein at least some of the protrusions are arranged at a radiation exit side of the component, and wherein a height of at least some of the protrusions corresponds at least to a height of the semiconductor chip.

This patent application is a national phase filing under section 371 of PCT/EP2020/076567, filed Sep. 23, 2020, which claims the priority of German patent application 102019126021.3, filed Sep. 26, 2019, each of which is incorporated herein by reference in its entirety.

### TECHNICAL FIELD

An optoelectronic semiconductor component and a method for producing an optoelectronic semiconductor component are specified.

### BACKGROUND

The optoelectronic semiconductor component is configured in particular for generating and/or detecting electromagnetic radiation, in particular light perceptible to the human eye.

### SUMMARY OF THE INVENTION

Embodiments provide an optoelectronic semiconductor component which has improved heat dissipation.

Further embodiment provide a method for producing, in a simplified manner, an optoelectronic semiconductor component having improved heat dissipation.

In accordance with at least one embodiment, the optoelectronic semiconductor component comprises a radiation exit side. The electromagnetic radiation emitted from the optoelectronic semiconductor component is coupled out at the radiation exit side of the optoelectronic semiconductor component.

In accordance with at least one embodiment, the optoelectronic semiconductor component comprises a heat dissipating structure having a plurality of protrusions. The heat dissipating structure is formed in particular with a material having a high thermal conductivity. The heat dissipating structure serves in particular for dissipating waste heat that arises during the operation of the optoelectronic semiconductor component. Impermissible heating of the semiconductor component is advantageously avoided as a result of the dissipation of waste heat.

A protrusion is a region of the heat dissipating structure which projects transversely, in particular perpendicularly, with respect to the main extension plane of the heat dissipating structure. The protrusions project beyond a region surrounding them.

In particular, the surface area of the heat dissipating structure is advantageously enlarged by means of the plurality of protrusions. A larger surface area enables improved heat dissipation by means of convection and/or radiant emission. The protrusions of the heat dissipating structure are oriented with respect to one another in particular regularly, for example at the grid points of a regular two-dimensional grid. The protrusions, in particular within the scope of production tolerance, are in particular identically shaped and embodied with the same geometric dimensions. By way of example, in particular within the scope of production tolerance, all the protrusions are embodied as solid cylinders having an identical diameter and an identical length. Furthermore, it is possible for the protrusions to be embodied in the form of grooves or lamellae.

In accordance with at least one embodiment, the heat dissipating structure is embodied in integral fashion. Preferably, the heat dissipating structure comprises a main body, at which the plurality of protrusions are arranged. The protrusions have in particular no interfaces with respect to the main body. Preferably, the protrusions are arranged directly at the main body. As a result, particularly good thermal linking of the protrusions can be affected, and heat dissipation by means of the heat dissipating structure is improved further.

In accordance with at least one embodiment, the optoelectronic semiconductor component comprises a radiation emitting semiconductor chip. The semiconductor chip comprises in particular a monolithic stack composed of a plurality of semiconductor layers deposited epitaxially.

The radiation emitting semiconductor chip preferably comprises an active region having a pn junction, a double heterostructure, a single quantum well (SQW) structure or a multi-quantum well (MQW) structure for generating radiation. The semiconductor component is a light emitting diode or a laser diode, for example.

In accordance with at least one embodiment of the optoelectronic semiconductor component, the semiconductor chip is arranged at the heat dissipating structure. An arrangement of the semiconductor chip at the heat dissipating structure enables heat to be dissipated from the semiconductor chip particularly well. In particular, the semiconductor chip is arranged directly at the heat dissipating structure. A direct arrangement of the semiconductor chip at the heat dissipating structure enables advantageously improved dissipation of heat from the semiconductor chip.

In accordance with at least one embodiment of the optoelectronic semiconductor component, at least some of the protrusions are arranged at the radiation exit side. In other words, the protrusions extend for example into a half-space around the radiation exit side into which the optoelectronic semiconductor component emits electromagnetic radiation.

The arrangement of protrusions at the radiation exit side advantageously enables a flat or substantially planar configuration of the semiconductor component at a rear side situated opposite the radiation exit side. Mounting of the optoelectronic semiconductor component is thus advantageously facilitated. If protrusions are arranged at the rear side as well, then the protrusions at the radiation exit side enable a particularly large area for dissipating heat.

In accordance with at least one embodiment of the optoelectronic semiconductor component, the optoelectronic semiconductor component comprises a radiation exit side,
a heat dissipating structure having a plurality of protrusions, and
a radiation emitting semiconductor chip, wherein
the semiconductor chip is arranged at the heat dissipating structure, and
at least some of the protrusions are arranged at the radiation exit side.

A optoelectronic semiconductor component described here is based on the following considerations, inter alia: waste heat arises during the operation of an optoelectronic semiconductor component and leads to the heating of the semiconductor component. In order to avoid an impermissibly high temperature of the semiconductor component, efficient dissipation of this heat is advantageous. For example, cooling structures for dissipating heat are mounted on the semiconductor component in a separate process step. In particular, the dissipation of heat from the semiconductor component is ensured by mounting on a thermally conductive connection carrier, for example a printed circuit board having a metal core. By way of example, the metal core of a so-called metal core circuit board is formed with copper. In particular, increased costs for the production of a semiconductor component can arise as a result of an additionally required process step and also as a result of the use of printed circuit boards having a thermally conductive core.

The optoelectronic semiconductor component described here makes use of the concept, inter alia, of already integrating a heat dissipating structure in the optoelectronic semiconductor component during the production thereof. The heat dissipating structure can thus be arranged particularly closely and tightly at the semiconductor chip producing the heat. Furthermore, the heat dissipating structure can be produced with other structures of the semiconductor component in a common method step. In particular, the heat dissipation is increased in the semiconductor component itself. Advantageously, mounting on a connection carrier which does not comprise a Cu core can also be affected as a result.

In accordance with at least one embodiment of the optoelectronic semiconductor component, the semiconductor chip is electrically contacted by means of the heat dissipating structure. In particular, the semiconductor chip is electrically contacted exclusively by means of the heat dissipating structure. The heat dissipating structure is embodied as electrically conductive, in particular. The heat dissipating structure thus has an electrical current-carrying capacity that is high enough to supply the semiconductor chip with a current required for the operation thereof. Advantageously, the heat dissipating structure fulfills a dual function as electrical conductor and as thermal conductor.

In accordance with at least one embodiment of the optoelectronic semiconductor component, the semiconductor chip is connected to the heat dissipating structure over the whole area. In the case of a connection over the whole area, the entire extension of at least one main area of the semiconductor component is in contact with the heat dissipating structure. Linking the semiconductor chip to the heat dissipating structure over the whole area enables particularly efficient dissipation of heat from the semiconductor chip.

In accordance with at least one embodiment of the optoelectronic semiconductor component, the heat dissipating structure is formed at least in places with at least one of the following materials: copper, aluminum, gold, diamond, diamond-like carbon (DLC), aluminum nitride. The material of the heat dissipating structure has in particular a particularly high thermal conductivity. By way of example, the heat dissipating structure is formed with a hybrid material composed of copper and diamond. Such a hybrid material advantageously has a particularly low coefficient of thermal expansion.

In accordance with at least one embodiment of the optoelectronic semiconductor component, at least some of the protrusions are arranged at a rear side of the semiconductor component situated opposite the radiation exit side. By way of example, protrusions are arranged at the rear side directly below the semiconductor chip. The arrangement of the rear-side protrusions spatially particularly close to the semiconductor chip enables advantageously particularly good dissipation of heat from the semiconductor chip.

In accordance with at least one embodiment of the optoelectronic semiconductor component, the optoelectronic semiconductor component comprises at least two connection bodies projecting beyond the protrusions at the rear side. The connection bodies are embodied as electrically conductive and serve for electrically supplying the semiconductor chip with an operating current. The connection bodies project beyond the protrusions at the rear side in their vertical extension. In other words, the connection bodies prevent or avoid a contact of the rear-side protrusions with an underlying area. Advantageously, the protrusions are thus protected against mechanical damage. Furthermore, the circulation of air through the protrusions is facilitated.

In accordance with at least one embodiment of the optoelectronic semiconductor component, at least some protrusions adjacent to one another are at a distance of at least 100 μm. The distance between adjacent protrusions is in particular equal to the width of the protrusions. An excessively small distance between the protrusions could impair the circulation of air between the protrusions. A sufficiently large distance is advantageous in order to ensure efficient dissipation of heat from the protrusions.

In accordance with at least one embodiment of the optoelectronic semiconductor component, a height of at least some of the protrusions corresponds to at least a height of the semiconductor chip. The height of the protrusions corresponds to their vertical extent. The vertical extent runs transversely, in particular perpendicularly, with respect to the main extension plane of the heat dissipating structure. In particular, the semiconductor chip is thus embedded in the heat dissipating structure. Shading of the electromagnetic radiation generated by the semiconductor chip during operation by the heat dissipating structure can advantageously be avoided if the extent of the protrusions in their vertical direction corresponds only to the height of the semiconductor chip itself.

In accordance with at least one embodiment of the optoelectronic semiconductor component, a height of at least some of the protrusions is at least 250 μm. A higher protrusion advantageously improves the dissipation of heat from the protrusion to the surroundings.

In accordance with at least one embodiment of the optoelectronic semiconductor component, at least some of the protrusions have a cylindrical shape and an axis of symmetry of at least one of the protrusions, in particular of all the protrusions, runs perpendicular to a main extension plane of the heat dissipating structure. The cylindrical protrusions are in particular simple to produce and ensure efficient heat dissipation of the heat dissipating structure. The orientation of the protrusions perpendicular to the main extension plane of the heat dissipating structure enables particularly efficient heat dissipation by convection.

In accordance with at least one embodiment of the optoelectronic semiconductor component, at least some of the protrusions have a width of at least 100 μm. The width of the protrusions corresponds to their maximum extent parallel to the main extension plane of the heat dissipating structure. The width of the protrusions determines, inter alia, their mechanical stability and the dissipation of heat from the main body into the protrusions.

In accordance with at least one embodiment of the optoelectronic semiconductor component, the heat dissipating structure has a frame body extending at least partly around, wherein the heat dissipating structure is in contact with the frame body at least in places. Preferably, the frame body is formed with an electrically insulating material. The frame body is formed for example with a polymer, in particular an epoxy. The frame body serves in particular for the mechanical stabilization of the optoelectronic semiconductor component.

In accordance with at least one embodiment of the optoelectronic semiconductor component, the frame body marginally completely surrounds the heat dissipating structure. The frame body is thus arranged as a closed frame around the heat dissipating structure. In particular, the frame body projects beyond the semiconductor chip in its vertical extent, transversely with respect to its main extension plane. As a result, the frame body can protect the semiconductor chip against mechanical damage.

In accordance with at least one embodiment of the optoelectronic semiconductor component, the heat dissipating structure comprises an electrically insulating substrate. The substrate is electrically insulating, but has a particularly high thermal conductivity. An electrically insulating substrate facilitates for example the electrical contacting of the semiconductor chip via the heat dissipating structure. Moreover, the substrate serves in particular for the mechanical stabilization of the heat dissipating structure. For this purpose, the substrate is embodied in particular in mechanically self-supporting fashion.

In accordance with at least one embodiment of the optoelectronic semiconductor component, the substrate is formed with a ceramic material, in particular with aluminum nitride. The ceramic material is distinguished in particular by a high thermal conductivity and a high mechanical stability. Furthermore, the ceramic material is preferably embodied as electrically insulating. Aluminum nitride is a ceramic material having a particularly high thermal conductivity.

In accordance with at least one embodiment of the optoelectronic semiconductor component, a cross-sectional area of the heat dissipating structure parallel to the main extension plane thereof corresponds at least to an eight-fold cross-sectional area of the semiconductor chip parallel to the main extension plane thereof. Preferably, a cross-sectional area of the heat dissipating structure parallel to the main extension plane thereof corresponds at least to a 20-fold area and particularly preferably to a 50-fold area of the cross-sectional area of the semiconductor chip parallel to the main extension plane thereof. The cross-sectional area should be understood as the lateral extent in a plan view. A larger area ratio advantageously enables better dissipation of heat from the semiconductor chip.

In accordance with at least one embodiment of the optoelectronic semiconductor component, the protrusions and the main body are formed with the same material. An integral heat dissipating structure can thus be embodied, in which in particular no interfaces between the main body and the protrusions exist. An integral embodiment of the heat dissipating structure enables a particularly high thermal conductivity. As a result, furthermore, thermally induced stresses between the protrusions and the main body can be reduced or avoided.

In accordance with at least one embodiment of the optoelectronic semiconductor component, the protrusions are connected to the main body without a further connecting material. By way of example, the protrusions are deposited or grown directly on the main body. A possible thermal resistance at an interface with respect to a connecting material is thus advantageously omitted. The heat dissipating structure can thus have a particularly high thermal conductivity.

A method for producing an optoelectronic semiconductor component is furthermore specified. The optoelectronic semiconductor component can be produced in particular by means of a method described here. That is to say that all features disclosed in association with the method for producing an optoelectronic semiconductor component are also disclosed for the optoelectronic semiconductor component, and vice versa.

In accordance with at least one embodiment of the method for producing an optoelectronic semiconductor component, the semiconductor component comprises a radiation exit side. Electromagnetic radiation generated in the semiconductor component during operation is coupled out on the radiation exit side.

In one step of the method for producing an optoelectronic semiconductor component, a substrate is provided. The substrate is formed with a material which is electrically insulating and which has a high thermal conductivity, in particular. By way of example, the substrate is formed with a ceramic material, in particular aluminum nitride. The substrate is preferably a mechanically stabilizing component part of the optoelectronic semiconductor component.

In accordance with at least one embodiment of the method for producing an optoelectronic semiconductor component, a main body is deposited at the side of the substrate facing the radiation exit side. The main body is formed in particular with an electrically conductive material that preferably has a high thermal conductivity. By way of example, the main body is formed with copper. The main body is deposited on the substrate in particular with a thickness that is uniform within the scope of production tolerance. In other words, the side of the substrate facing the radiation exit side is in particular completely covered by the main body.

In accordance with at least one embodiment of the optoelectronic semiconductor component, the thickness of the main body is between 10 μm and 1000 μm inclusive. Preferably, the thickness of the main body is between 30 μm and 200 μm inclusive, and particularly preferably between 50 μm and 100 μm. The thickness of the main body corresponds to the extent thereof perpendicular to the main extension plane thereof. A larger thickness advantageously enables improved heat dissipation. However, a particularly thick main body requires a substrate having an adapted coefficient of thermal expansion.

In accordance with at least one embodiment of the method for producing an optoelectronic semiconductor component, protrusions are deposited onto the main body. The main body and the protrusions form in particular a heat dissipating structure. A protrusion is a region of the heat dissipating structure that projects transversely, in particular perpendicularly, with respect to the main extension plane of the main body. The protrusions project beyond a region of the main body surrounding them.

In particular, the surface area of the main body is advantageously enlarged by means of the plurality of protrusions. A larger surface area enables improved heat dissipation by means, for example, of convection and/or radiant emission. The protrusions of the heat dissipating structure are oriented with respect to one another in particular regularly, for example at the grid points of a regular two-dimensional grid. The protrusions, in particular within the scope of production tolerance, are in particular identically shaped and embodied with the same geometric dimensions. By way of example, in particular within the scope of production tolerance, all the protrusions are embodied as solid cylinders having an identical diameter and an identical length. Furthermore, it is possible for the protrusions to be embodied in the form of grooves or lamellae.

In accordance with at least one embodiment of the method for producing an optoelectronic semiconductor component, the protrusions and the main body are formed with the same material. An integral heat dissipating structure can thus be embodied, in which in particular no interfaces between the main body and the protrusions exist. An integral embodiment enables a particularly high thermal conductivity of the heat dissipating structure. The deposition or the growth of protrusions on the main body is advantageously simplified if the protrusions and the main body are formed with the same material. Furthermore, thermally induced stresses between the protrusions and the main body can be reduced or avoided.

In accordance with at least one embodiment of the method for producing an optoelectronic semiconductor component, the protrusions are connected to the main body without a further connecting material. By way of example, the protrusions are deposited or grown directly on the main body. A possible thermal resistance at an interface with respect to a connecting material is thus advantageously omitted. The heat dissipating structure can thus have a particularly high thermal conductivity.

In accordance with at least one embodiment of the method for producing an optoelectronic semiconductor component, before the protrusions are deposited, a mask layer is deposited on the main body and cutouts are introduced into the mask layer. The mask layer is formed with a photoresist, in particular. In particular, the mask layer comprises a plurality of layers arranged one above another in order to achieve a sufficient height or thickness of the mask layer. The cutouts preferably completely penetrate through the mask layer. The cutouts are filled in particular with the material of the protrusions. The mask layer can subsequently be removed again.

In accordance with at least one embodiment of the method for producing an optoelectronic semiconductor component, the main body is deposited by means of electroplating. Electroplating enables a material, such as copper, for example, to be deposited on a planar support in a particularly simple manner. Preferably, in this case, a main body can be produced with a particularly homogeneous thickness along its lateral extension.

In accordance with at least one embodiment of the method for producing an optoelectronic semiconductor component, the protrusions are deposited by means of electroplating. By means of electroplating, it is possible to produce protrusions with an advantageously high aspect ratio, in particular.

In accordance with at least one embodiment of the method for producing an optoelectronic semiconductor component, protrusions are produced at the radiation exit side and at a rear side of the substrate, said rear side being situated opposite the radiation exit side, simultaneously in a common method step. This advantageously ensures that the protrusions are produced at both sides of the substrate with an identical height. Particularly advantageously, as a result only a single method step is necessary in order to provide both sides of the semiconductor component with protrusions.

In accordance with at least one embodiment of the method for producing an optoelectronic semiconductor component, an optoelectronic semiconductor component described here is produced.

In accordance with at least one embodiment of the method for producing an optoelectronic semiconductor component, a semiconductor chip is mounted on the main body.

A optoelectronic semiconductor component described here is suitable in particular for use as a high-power light emitting diode in an automobile headlight, for example, or as a light source in a projection application.

### BRIEF DESCRIPTION OF THE DRAWINGS

Further advantages and advantageous configurations and developments of the optoelectronic semiconductor component will become apparent from the following exemplary embodiments, in association with those illustrated in the figures.

FIG. 1 shows a schematic sectional view of an optoelectronic semiconductor component described here in accordance with a first exemplary embodiment;

FIGS. 2A-2C show schematic plan views of optoelectronic semiconductor components described here in accordance with a second, a third and a fourth exemplary embodiment;

FIG. 3 shows a schematic sectional view of an optoelectronic semiconductor component described here in accordance with a fifth exemplary embodiment; and

FIG. 4 shows a schematic sectional view of an optoelectronic semiconductor component described here in accordance with a sixth exemplary embodiment.

### DETAILED DESCRIPTION OF ILLUSTRATIVE EMBODIMENTS

Elements that are identical, of identical type or act identically are provided with the same reference signs in the figures. The figures and the size relationships of the elements illustrated in the figures among one another should not be regarded as to scale. Rather, individual elements may be illustrated with an exaggerated size in order to enable better illustration and/or in order to afford a better understanding.

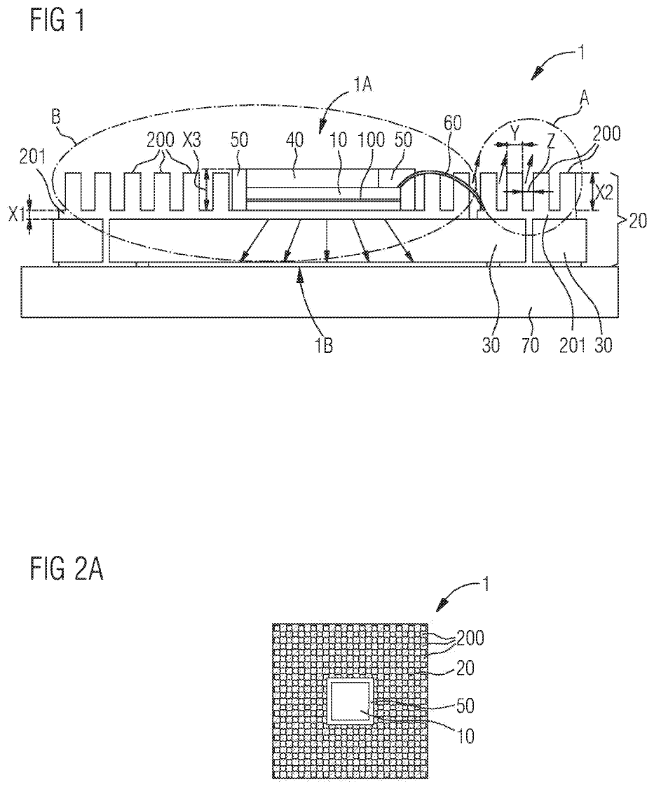

FIG. 1 shows a schematic sectional view of an optoelectronic semiconductor component 1 described here in accordance with the first exemplary embodiment. The optoelectronic semiconductor component 1 comprises a radiation exit side 1A and a rear side 1B situated opposite the radiation exit side 1A. At the radiation exit side 1A, electromagnetic radiation is coupled out from the semiconductor component 1.

At the radiation exit side 1A, a semiconductor chip 10 is arranged as a heat dissipating structure 20. The semiconductor chip 10 comprises an active region 100 configured for emitting electromagnetic radiation and having a pn junction.

Furthermore, the semiconductor chip 10 comprises an optional conversion element 40 at the side facing away from the heat dissipating structure 20. The conversion element 40 is configured for converting electromagnetic radiation having a first wavelength to electromagnetic radiation having a second wavelength, where the first wavelength differs from the second wavelength. At least one portion of the electromagnetic radiation emitted by the active region 100 during operation is converted by the conversion element 40. The conversion element 40 is formed with a translucent matrix material, for example, into which particles of a wavelength-converting material are embedded.

The semiconductor chip 10 has a height X3. The height X3 of the semiconductor chip 10 describes a vertical extent of the semiconductor chip 10 in a direction perpendicular to the main extension plane of the semiconductor chip 10. The height X3 of the semiconductor chip 10 is composed of the height of the epitaxially deposited semiconductor layers and the height of a conversion element 40 optionally arranged on the semiconductor layers.

In its lateral extent the semiconductor chip 10 is delimited by a molded body 50. The molded body 50 comprises for example an epoxy filled with a reflective filler, such as titanium dioxide, for example. The molded body 50 reduces or prevents lateral coupling of electromagnetic radiation out of the semiconductor chip 10. Furthermore, the molded body 50 serves for encapsulating the semiconductor chip 10 against harmful environmental influences.

The heat dissipating structure 20 comprises a substrate 30 and also a main body 201 and a plurality of protrusions 200. The substrate 30 in this exemplary embodiment is formed with a ceramic material, in particular aluminum nitride. Aluminum nitride has a particularly good thermal conductivity and is electrically insulating. The substrate 30 serves as a mechanically stabilizing element of the heat dissipating structure 20. The substrate 30 has feedthroughs for electrical connections provided for contacting the semiconductor chip 10. The main body 201 and the plurality of protrusions 200 are arranged at the substrate 30. The protrusions 200 and the main body 201 are formed with the same material. The main body 201 and the protrusions 200 are preferably formed with copper. The main body 201 and the protrusions 200 are embodied in integral fashion. The main body 201 is deposited on the substrate 30 by means of electroplating. The semiconductor chip 10 is arranged on the main body 201. This enables particularly good dissipation of heat from the semiconductor chip 10 into the heat dissipating structure 20.

The main body 201 has a thickness X1. The thickness X1 of the main body 201 corresponds to the extent thereof perpendicular to the main extension plane thereof. The thickness X1 of the main body 201 is between 10 μm and 1000 μm inclusive. Preferably, the thickness X1 of the main body 201 is between 30 μm and 200 μm inclusive, and particularly preferably between 50 μm and 100 μm. A larger thickness X1 of the main body 201 increases the heat dissipation of the main body 201. The thickness X1 of the main body 201 is restricted upward by a possibly unsuitable coefficient of thermal expansion between the material of the main body 201 and the substrate 30. A thickness X1 of the main body 201 of between 50 μm and 100 μm has proved to be particularly advantageous in this case.

The protrusions 200 are applied on the main body 201 by means of electroplating. The protrusions 200 are shaped for example as solid cylinders, as lamellae or as grooves. The protrusions 200 extend into a half-space around the radiation exit side 1A into which the optoelectronic semiconductor component 1 emits electromagnetic radiation. The protrusions 200 are at a distance Z of 100 μm from one another. A smaller distance Z between the protrusions 200 enables a higher density of the protrusions 200. If a distance Z between the protrusions 200 is excessively small, however, the dissipation of heat by means of convection can disadvantageously be made more difficult. A distance Z between the protrusions 200 of 100 μm has proved to be particularly advantageous.

The protrusions 200 have a height X2. The height X2 of the protrusions 200 describes a vertical extent of the protrusions 200 in a direction perpendicular to the main extension plane of the heat dissipating structure 20. The height X2 of the protrusions 200 is 250 μm. A larger height X2 of the protrusions 200 can advantageously increase the dissipation of heat from the heat dissipating structure 20. The height X2 of the protrusions 200 preferably corresponds at most to the height X3 of the semiconductor chip 10. Shading of the electromagnetic radiation emerging from the semiconductor chip 10 by the protrusions 200 is advantageously avoided as a result.

The protrusions 200 furthermore have a width Y. The width Y of the protrusions 200 describes a lateral extent of the protrusions 200 in a direction parallel to the main extension plane of the heat dissipating structure 20. The width of a protrusion 200 shaped as a groove or lamella is defined by the extent of the groove in a direction transversely with respect to the main extension direction thereof. The width Y of the protrusions 200 is 100 μm. A smaller width Y of the protrusions 200 increases the possible density of protrusions 200, but can reduce the dissipation of heat from the main layer 201 into the protrusions 200. A width Y of the protrusions 200 of 100 μm has proved to be particularly advantageous.

The semiconductor chip 10 is electrically contacted by means of the heat dissipating structure 20. For this purpose, the heat dissipating structure 20 is divided into at least two regions A and B which are electrically insulated from one another. A connection wire 60 is arranged at the first region A of the heat dissipating structure 20, and is connected to the side of the semiconductor chip 10 facing away from the substrate 30. The connection wire 60 is formed with a bond wire. The semiconductor chip 10 is arranged at the second region B of the heat dissipating structure 20.

The entire heat dissipating body 20 and the semiconductor chip 10 are arranged on a connection carrier 70. The connection carrier 70 is a printed circuit board or a PCB formed with an epoxy. The heat dissipating structure 20 dissipates one portion of the waste heat generated in the semiconductor chip 10 during operation by means of convection and radiant emission from the heat dissipating structure 20. A further portion of the waste heat of the semiconductor chip 10 is dissipated by means of heat conduction through the substrate 30 into the connection carrier 70. That portion of the waste heat which is dissipated via the substrate 30 is significantly reduced by comparison with an embodiment without the heat dissipating body 20. Impermissible heating of the semiconductor chip 10 is advantageously avoided in this way. Furthermore, use of materials having a lower thermal conductivity is advantageously made possible for the substrate 30.

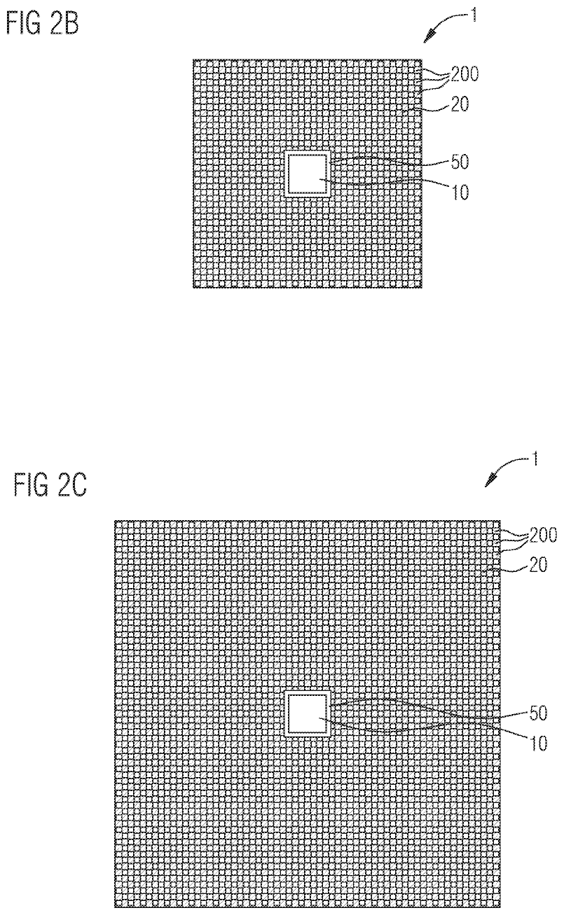

FIGS. 2A to 2C show schematic plan views of optoelectronic semiconductor components described here in accordance with the second, the third and the fourth exemplary embodiment.

The second exemplary embodiment shown in FIG. 2A comprises an optoelectronic semiconductor component 1, the semiconductor chip 10 of which is surrounded by a molded body 50 and a plurality of protrusions 200 of a heat dissipating element 20. The lateral area of the heat dissipating structure 20 in a cross-sectional area parallel to the plane of the drawing amounts to eight times the cross-sectional area of the semiconductor chip 10 parallel to the plane of the drawing. By means of such a configuration of an optoelectronic semiconductor component 1, the surface area of the semiconductor component 1 is advantageously enlarged, whereby improved dissipation of heat from the semiconductor component 1 is achieved.

The third exemplary embodiment illustrated in FIG. 2B comprises an optoelectronic semiconductor component 1, the semiconductor chip 10 of which is surrounded by a molded body 50 and a plurality of protrusions 200 of a heat dissipating element 20. The edge length of the heat dissipating structure 20 is increased by comparison with the second exemplary embodiment illustrated in FIG. 2A. The larger edge length also produces a larger cross-sectional area parallel to the plane of the drawing and thus enables improved heat dissipation. The lateral area of the heat dissipating structure 20 in a cross-sectional area parallel to the plane of the drawing amounts to 18 times the cross-sectional area of the semiconductor chip 10 parallel to the plane of the drawing. The further enlarged surface area of the heat dissipating structure 20 is associated with further improved dissipation of heat from the semiconductor component 1.

The fourth exemplary embodiment shown in FIG. 2C comprises an optoelectronic semiconductor component 1, the semiconductor chip 10 of which is surrounded by a molded body 50 and a plurality of protrusions 200 of a heat dissipating element 20. The edge length of the heat dissipating structure 20 is increased further by comparison with the third exemplary embodiment illustrated in FIG. 2B. Such a large edge length enables the cross-sectional area of the heat dissipating element 20 to be enlarged further. The lateral area of the heat dissipating structure 20 in a cross-sectional area parallel to the plane of the drawing amounts to 50 times the cross-sectional area of the semiconductor chip 10 parallel to the plane of the drawing. The further enlarged surface area of the heat dissipating structure 20 is associated with further improved dissipation of heat from the semiconductor component 1.

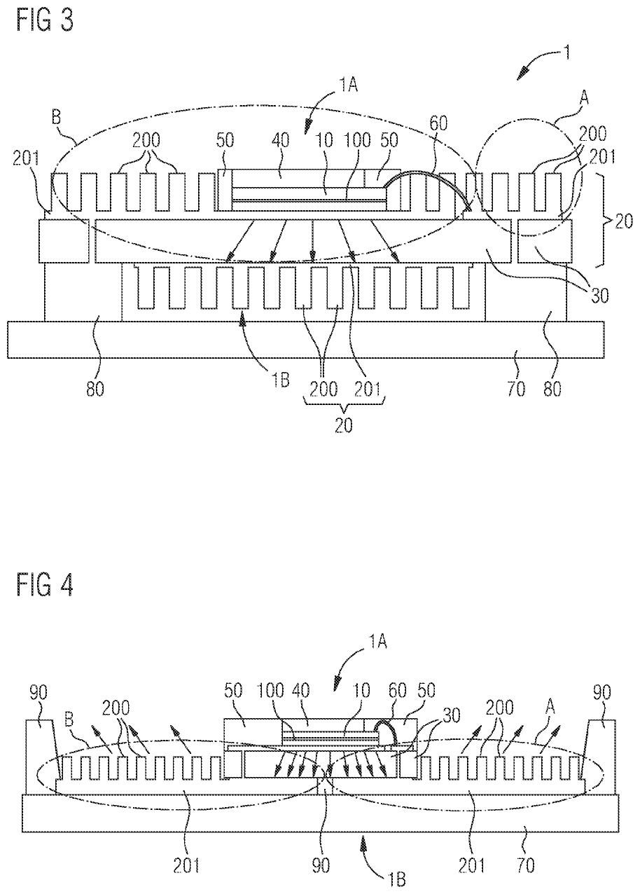

FIG. 3 shows a schematic sectional view of an optoelectronic semiconductor component 1 described here in accordance with the fifth exemplary embodiment. A plurality of connection bodies 80 are arranged at a rear side 1B of the substrate 30 facing away from the radiation exit side 1A. The connection bodies 80 serve as spacers separating the heat dissipating structure 20 from a connection carrier 70. The semiconductor chip 10 is supplied with an electrical operating voltage by means of the connection bodies 80.

Furthermore, the exemplary embodiment shown here also comprises a main body 201 with protrusions 200 at the rear side B. The free-standing protrusions 200 at the rear side 1B are arranged particularly close to the semiconductor chip 10, whereby good dissipation of heat is made possible. The arrangement of protrusions 200 both at the radiation exit side 1A and at the rear side 1B thus enables particularly efficient dissipation of heat from the semiconductor chip 10. The connection bodies 80 project beyond the protrusions 200 on the rear side B. This ensures particularly good circulation of air through the protrusions 200 arranged on the rear side B.

FIG. 4 shows a schematic sectional view of an optoelectronic semiconductor component described here in accordance with the sixth exemplary embodiment. The optoelectronic semiconductor component 1 shown here comprises a frame body 90 marginally surrounding the heat dissipating structure 20. The frame body go is formed with an epoxy. The frame body go increases the mechanical stability of the optoelectronic semiconductor component 1.

The heat dissipating structure 20 is embedded into the frame body go. The heat dissipating structure 20 is in contact with the frame body 90 at least in places. The frame body go is embodied as electrically insulating. The frame body 90 terminates flush with the semiconductor chip 10 in a vertical direction. The vertical direction runs perpendicular to the main extension plane of the frame body go. As a result, the semiconductor chip 10 is protected against mechanical damage particularly well. Preferably, the frame body 90 covers as little area of the heat dissipating structure 20 as possible in order that the dissipation of heat from the heat dissipating structure 20 is impaired as little as possible.

In this exemplary embodiment, the thickness X1 of the main body 201 is advantageously not restricted by a possibly unsuitable coefficient of thermal expansion between the main body 201 and the substrate 30, since the contact area between the main body 201 and the substrate 30 is smaller. The coefficient of thermal expansion of the heat dissipating structure 20 is thus able to be chosen independently of the coefficient of thermal expansion of the substrate 30. The heat dissipating structure 20 serves both for mechanical stabilization and for electrical connection of the semiconductor chip 10 and mounting of the frame body go. The first region A of the heat dissipating structure 20 is electrically insulated from the second region B of the heat dissipating structure 20. The first region A of the heat dissipating structure 20 is electrically insulated from the second region B of the heat dissipating structure 20 by means of the frame body go.

The molded body 50 is arranged at the semiconductor chip 10 at the substrate 30. The molded body completely covers the side of the substrate 30 facing the semiconductor chip 10.

The invention is not restricted by the description on the basis of the exemplary embodiments. Rather, the invention encompasses any novel feature and also any combination of features, which in particular includes any combination of features in the patent claims, even if this feature or this combination itself is not explicitly specified in the patent claims or exemplary embodiments.

1.-20. (canceled)

21. An optoelectronic semiconductor component having a radiation exit side, the optoelectronic semiconductor component comprising:
a heat dissipating structure having a plurality of protrusions; and
a radiation emitting semiconductor chip,
wherein the semiconductor chip is arranged at the heat dissipating structure,
wherein at least some of the protrusions are arranged at the radiation exit side, and
wherein a height of at least some of the protrusions corresponds at least to a height of the semiconductor chip.

22. The optoelectronic semiconductor component of claim 21, wherein the semiconductor chip is electrically contactable by the heat dissipating structure.

23. The optoelectronic semiconductor component of claim 21, wherein the semiconductor chip is connected to the heat dissipating structure over an entire area.

24. The optoelectronic semiconductor component of claim 21, wherein the heat dissipating structure comprises one of the following materials: Cu, Al, Au, diamond, diamond-like carbon, or AlN.

25. The optoelectronic semiconductor component of claim 21, wherein at least some of the protrusions are arranged at a rear side situated opposite the radiation exit side.

26. The optoelectronic semiconductor component of claim 25, further comprising at least two connection bodies projecting beyond the protrusions at the rear side.

27. The optoelectronic semiconductor component of claim 21, wherein at least some protrusions adjacent to one another are at a distance of at least 100 μm from one another.

28. The optoelectronic semiconductor component of claim 21, wherein the semiconductor chip is arranged on a main body of the heat dissipating structure.

29. The optoelectronic semiconductor component of claim 21, wherein at least some of the protrusions have a cylindrical shape and an axis of symmetry of at least one of the protrusions runs perpendicular to a main extension plane of the heat dissipating structure.

30. The optoelectronic semiconductor component of claim 21, wherein at least some of the protrusions comprises webs whose main extension directions run parallel to a main extension plane of the heat dissipating structure.

31. The optoelectronic semiconductor component of claim 21, further comprising a frame body extending at least partly around the heat dissipating structure, wherein the heat dissipating structure is in contact with the frame body at least in places.

32. The optoelectronic semiconductor component of claim 31, wherein the frame body marginally completely surrounds the heat dissipating structure.

33. The optoelectronic semiconductor component of claim 21, wherein the heat dissipating structure comprises an electrically insulating substrate.

34. The optoelectronic semiconductor component of claim 33, wherein the substrate comprises a ceramic material.

35. The optoelectronic semiconductor component of claim 21, wherein a cross-sectional area of the heat dissipating structure parallel to a main extension plane thereof corresponds at least to an eight-fold cross-sectional area of the semiconductor chip parallel to a main extension plane thereof.

36. A method for producing an optoelectronic semiconductor component having a radiation exit side, the method comprising:
providing a substrate;
depositing a main body at a side of the substrate facing the radiation exit side;
depositing protrusions on the main body in order to form a heat dissipating structure; and
arranging a semiconductor chip at the heat dissipating structure,
wherein a height of at least some of the protrusions corresponds at most to a height of the semiconductor chip.

37. The method of claim 36, wherein depositing the main body comprises electroplating.

38. The method of claim 36, wherein depositing the protrusions comprises electroplating.

39. The method of claim 36, wherein the protrusions are produced at the radiation exit side and at a rear side of the substrate simultaneously, the rear side being situated opposite the radiation exit side.
